(19) United States
(12) Patent Application Publication
(10) Pub. No.: US 2022/0392665 A1
(43) Pub. Date: Dec. 8, 2022

(54) VIBRATION ABSORBING ASSEMBLY AND SERVER

(71) Applicants: Inventec (Pudong) Technology Corporation, Shanghai (CN); Inventec Corporation, Taipei (TW)

(72) Inventors: Han-Chih HSIEH, Taipei (TW); Po-Hsiu CHEN, Taipei (TW); Guo-Sing Yang, Taipei (TW); Ruei-Hsi TU, Taipei (TW)

(21) Appl. No.: 17/475,447

(22) Filed: Sep. 15, 2021

(30) Foreign Application Priority Data
Jun. 3, 2021 (CN) 202110628889.8

(51) Int. Cl. H01B 7/24; H05K 7/20

(52) U.S. Cl. CPC H01B 7/24; H05K 7/20718

(57) ABSTRACT

A vibration absorbing assembly is adapted to be disposed on a cable. The vibration absorbing assembly includes a mount frame and a flexible covering component. The mount frame includes a first part and a second part. The second part is detachably assembled with the first part, and the first part and the second part together form an accommodation space. The flexible covering component is located in the accommodation space and pressed by the first part and the second part so as to surround a covering space. The covering space is configured to accommodate the cable.

### CROSS-REFERENCE TO RELATED APPLICATIONS

This non-provisional application claims priority under 35 U.S.C. § 119(a) on Patent Application No(s). 202110628889.8 filed in China, on Jun. 3, 2021, the entire contents of which are hereby incorporated by reference.

### BACKGROUND OF THE INVENTION

### Technical Field of the Invention

The invention relates to a vibration absorbing assembly and a server, more particularly to a vibration absorbing assembly having a flexible covering component and a server including the same.

### Description of the Related Art

In the present, servers are widely used by enterprises. The servers are combined with the applications of the Internet and the telecommunication industry. The servers can be applied in various fields, such as financial business, online bank business, online credit card business and so on.

In general, the servers are installed on a rack, and the mainstream servers are 1U servers. In one 1U server, it has a height about 1.75 inches (4.5 centimeters), such that the 1U server occupies less space and can be managed more efficiently than a conventional large server. Besides, the 1U server has slim, lightweight, and stackable characteristics, such that it is widely used in the market. In order to store a large amount of data, the server is required to equip many storage devices (e.g., hard disk drives). However, fans in the server may generate vibrations, and the vibration may be transmitted to the storage devices, causing abnormal of reading and writing data in the storage devices.

### SUMMARY OF THE INVENTION

The invention provides a vibration absorbing assembly and a server which are capable of reducing the vibration transmitted to interior components of the server.

One embodiment of the invention provides a vibration absorbing assembly. The vibration absorbing assembly is adapted to be disposed on a cable. The vibration absorbing assembly includes a mount frame and a flexible covering component. The mount frame includes a first part and a second part. The second part is detachably assembled with the first part, and the first part and the second part together form an accommodation space. The flexible covering component is located in the accommodation space and pressed by the first part and the second part so as to surround a covering space. The covering space is configured to accommodate the cable.

Another embodiment of the invention provides a server. The server includes a casing, a storage module, a fan module, and a vibration absorbing assembly. The storage module is disposed on the casing. The fan module is disposed on the casing and spaced apart from the storage module. The vibration absorbing assembly is stacked on the casing and located between the fan module and the storage module. The vibration absorbing assembly is adapted to be disposed on a cable. The vibration absorbing assembly includes a mount frame and a flexible covering component. The mount frame includes a first part and a second part. The second part is detachably assembled with the first part, and the first part and the second part together form an accommodation space. The flexible covering component is located in the accommodation space and pressed by the first part and the second part so as to surround a covering space. The covering space is configured to accommodate the cable.

According to the vibration absorbing assembly and the server as discussed in the above embodiments, the flexible covering component can be rapidly disposed on a desired position where the cable or another object suitable for the installation of the flexible covering component is located via the mount frame for absorbing the vibration. In addition, the size of the vibration absorbing assembly and the thickness and the material of the flexible covering component can be rapidly modified according to the result of the vibration simulation. Therefore, compared to a case that uses cushion or the like for absorbing the vibration, using the vibration absorbing assembly can save time spending on cutting the cushion or the like into adequate sizes, adjusting its position, and adhering it on the desired position.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of a vibration absorbing assembly according to one embodiment of the invention and a cable;

FIG. 2 is a partial exploded view of the vibration absorbing assembly in FIG. 1;

FIG. 3 is an exploded view of the vibration absorbing assembly in FIG. 2; and

FIG. 4 is a schematic view of a server including the vibration absorbing assembly in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

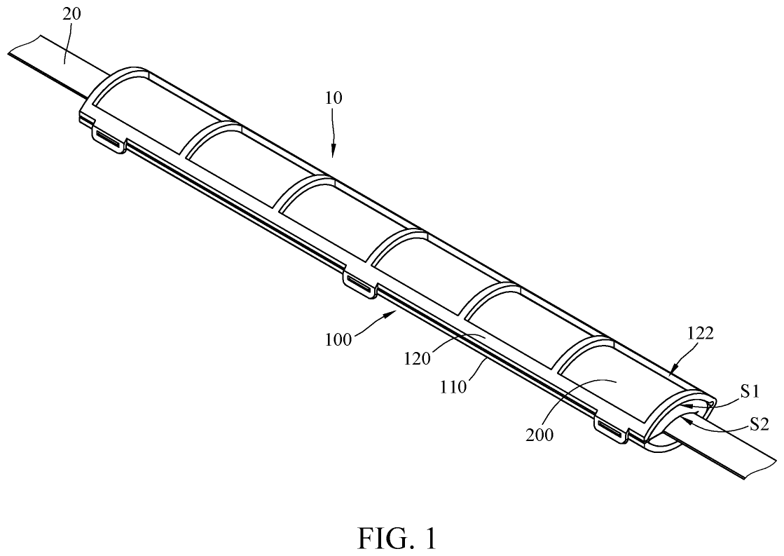

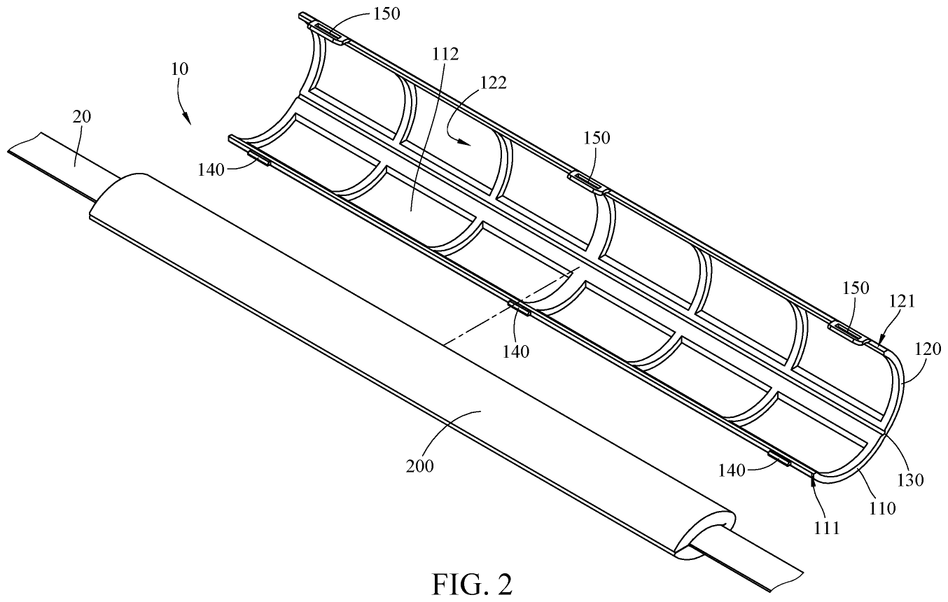

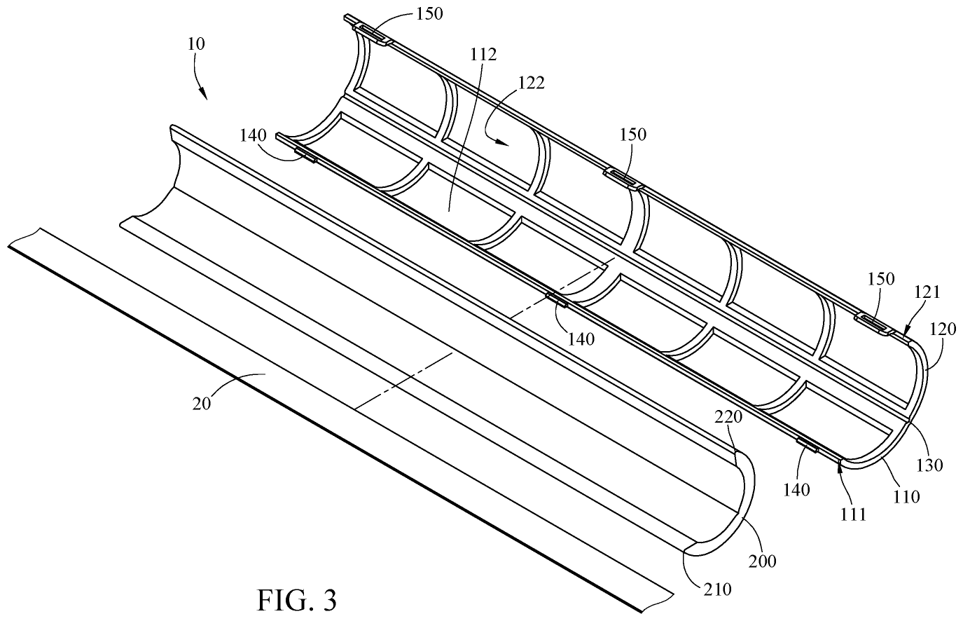

Referring to FIGS. 1 to 3, there are shown a perspective view, a partial exploded view, and an exploded view of a vibration absorbing assembly 10 according to one embodiment of the invention and a cable.

In this embodiment, the vibration absorbing assembly 10 is adapted to be disposed on an object, such as a cable 20. The vibration absorbing assembly 10 includes a mount frame 100 and a flexible covering component 200. The mount frame 100 includes a first part 110 and a second part 120. The second part 120 is detachably assembled with the first part 110, such that the first part 110 and the second part 120 together form an accommodation space S1 therebetween.

Specifically, the mount frame 100 may further include a flexible connection part 130. A side of the first part 110 and a side of the second part 120 are connected to each other via the flexible connection part 130. The mount frame 100 may further include a plurality of first fastening parts 140 and a plurality of second fastening parts 150. The first fastening parts 140 are disposed at another side 111 of the first part 110 located away from the flexible connection part 130. The second fastening parts 150 are disposed at another side 121 of the second part 120 located away from the flexible connection part 130. The second fastening parts 150 are respectively and detachably fastened with the first fastening parts 140, such that the first part 110 and the second part 120 together form the accommodation space S1.

In this embodiment, the first fastening parts 140 are engagement blocks, and the second fastening parts 150 are engagement holes; but the forms of the first fastening parts 140 and the second fastening parts 150 are not restricted and may be modified as required;

in some other embodiments, the first fastening parts and the second fastening parts may be assembled with each other via any suitable means, such as a screw or a magnet.

In this embodiment, the first part 110 may have a plurality of through holes 112, and the second part 120 may have a plurality of through holes 122. The through holes 112 and 122 can reduce the overall weight and rigidity of the vibration absorbing assembly 10 so as to increase the vibration absorbing effect of the vibration absorbing assembly 10.

Note that the quantities of the through holes 112 and 122, the first fastening parts 140, and the second fastening parts 150 are not restricted in the invention and may be modified as required; in some other embodiments, the first part may have only one through hole, the second part may have only one through hole, and the mount frame may include only one first fastening part and only one second fastening part.

When there is no force applied on the flexible covering component 200, the flexible covering component 200 may be a curved plate body, but the invention is not limited thereto; in some other embodiments, the flexible covering component may be a flat plate body. The flexible covering component 200 is located in the accommodation space S1. The flexible covering component 200 has a first side 210 and a second side 220 located opposite to each other. The first side 210 of the flexible covering component 200 is pressed by the first part 110, and the second side 220 of the flexible covering component 200 is pressed by the second part 120, such that the flexible covering component 200 surrounds a covering space S2. The covering space S2 is configured to accommodate the cable 20.

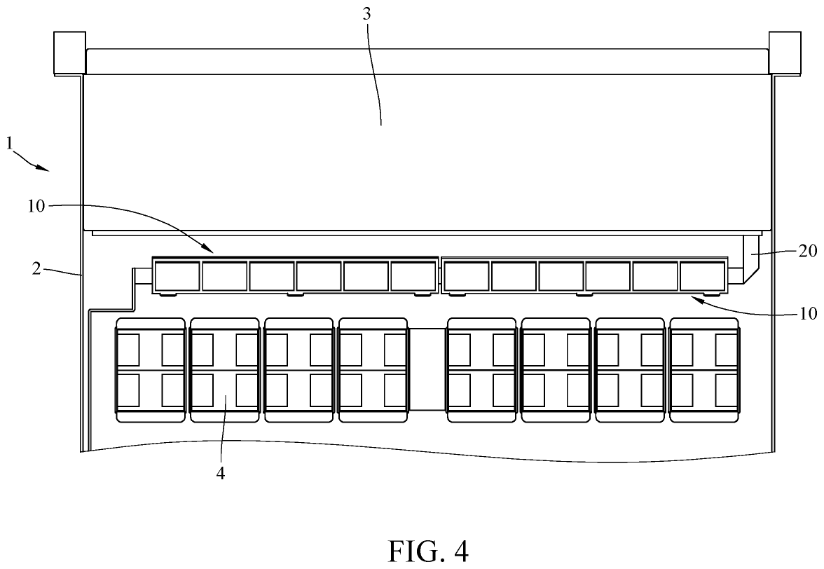

In this embodiment, the flexible covering component 200 can be rapidly disposed on a desired position where the cable 20 or another object suitable for the installation of the flexible covering component 200 is located via the mount frame 100 for absorbing the vibration. In addition, the size of the vibration absorbing assembly 10 and the thickness and the material of the flexible covering component 200 can be rapidly modified according to the result of the vibration simulation. Therefore, compared to a case that uses cushion or the like for absorbing the vibration, using the vibration absorbing assembly 10 can save time spending on cutting the cushion or the like into adequate sizes, adjusting its position, and adhering it on the desired position. In detail, referring to FIG. 4, there is shown a schematic view of a server 1 including the vibration absorbing assembly 10 in FIG. 1. The server 1 includes a casing 2, a storage module 3, a fan module 4, and the vibration absorbing assembly 10. The storage module 3 is disposed on the casing 2. The fan module 4 is disposed on the casing 2 and spaced apart from the storage module 3. In general, during the operation of the server 1, the vibration generated by the fan module 4 may be transmitted to the storage module 3 via the cable 20 located between the fan module 4 and the storage module 3 so as to adversely affect the performance of the storage module 3. At this case, the vibration absorbing assembly 10 can be stacked on the casing 2 and rapidly installed on the cable 20 located between the fan module 4 and the storage module 3 by wrapping the flexible covering component 200 on the cable 20 via the mount frame 100. As a result, the vibration absorbing assembly 10 can be installed on the desired position in a convenient manner and prevent the vibration generated by the fan module 4 from transmitting to the storage module 3.

According to the vibration absorbing assembly and the server as discussed in the above embodiments, the flexible covering component can be rapidly disposed on a desired position where the cable or another object suitable for the installation of the flexible covering component is located via the mount frame for absorbing the vibration. In addition, the size of the vibration absorbing assembly and the thickness and the material of the flexible covering component can be rapidly modified according to the result of the vibration simulation. Therefore, compared to a case that uses cushion or the like for absorbing the vibration, using the vibration absorbing assembly can save time spending on cutting the cushion or the like into adequate sizes, adjusting its position, and adhering it on the desired position.

In one embodiment, the server (i.e., electronic device) disclosed by the invention can be applied to artificial intelligence (AI) computing, edge computing and can be used as 5G server, cloud computing server, or internet of vehicle server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A vibration absorbing assembly, adapted to be disposed on a cable, comprising:
a mount frame, comprising a first part and a second part, wherein the second part is detachably assembled with the first part, and the first part and the second part together form an accommodation space; and
a flexible covering component, located in the accommodation space and pressed by the first part and the second part so as to surround a covering space, wherein the covering space is configured to accommodate the cable.

2. The vibration absorbing assembly according to claim 1, wherein the mount frame further comprises a flexible connection part, and a side of the first part and a side of the second part are connected to each other via the flexible connection part.

3. The vibration absorbing assembly according to claim 2, wherein the mount frame further comprises at least one first fastening part and at least one second fastening part, the at least one first fastening part is disposed at a side of the first part located away from the flexible connection part, the at least one second fastening part is disposed at a side of the second part located away from the flexible connection part, and the at least one second fastening part is detachably fastened with the at least one first fastening part.

4. The vibration absorbing assembly according to claim 3, wherein the at least one first fastening part is an engagement block, and the at least one second fastening part is an engagement hole.

5. The vibration absorbing assembly according to claim 1, wherein each of the first part and the second part has at least one through hole.

6. A server, comprising:
a casing;
a storage module, disposed on the casing;
a fan module, disposed on the casing and spaced apart from the storage module; and
a vibration absorbing assembly, stacked on the casing and located between the fan module and the storage module, wherein the vibration absorbing assembly is adapted to be disposed on a cable, and the vibration absorbing assembly comprises:
a mount frame, comprising a first part and a second part, wherein the second part is detachably assembled with the first part, and the first part and the second part together form an accommodation space; and
a flexible covering component, located in the accommodation space and pressed by the first part and the second part so as to surround a covering space, wherein the covering space is configured to accommodate the cable.

7. The server according to claim 6, wherein the mount frame further comprises a flexible connection part, and a side of the first part and a side of the second part are connected to each other via the flexible connection part.

8. The server according to claim 7, wherein the mount frame further comprises at least one first fastening part and at least one second fastening part, the at least one first fastening part is disposed at a side of the first part located away from the flexible connection part, the at least one second fastening part is disposed at a side of the second part located away from the flexible connection part, and the at least one second fastening part is detachably fastened with the at least one first fastening part.

9. The server according to claim 8, wherein the at least one first fastening part is an engagement block, and the at least one second fastening part is an engagement hole.

10. The server according to claim 6, wherein each of the first part and the second part has at least one through hole.
